(19) United States
(12) Patent Application Publication
(10) Pub. No.: US 2026/0190631 A1
(43) Pub. Date: Jul. 2, 2026

(54) Light-Emitting Device, Preparation Method Therefor, and Electronic Apparatus Comprising Same

(71) Applicant: NAJING TECHNOLOGY CORPORATION LIMITED, Hangzhou, Zhejiang (CN)

(72) Inventors: Changgua ZHEN, Hangzhou, Zhejiang (CN); Junjun PENG, Hangzhou, Zhejiang (CN)

(21) Appl. No.: 18/862,543

(22) PCT Filed: Aug. 9, 2023
(86) PCT No.: PCT/CN2023/111889

§ 371 Date: Nov. 3, 2024

(51) Int. Cl. H10K 59/122; H10K 59/12; H10K 59/35

(52) U.S. Cl. CPC H10K 59/122; H10K 59/1201; H10K 59/352

(57) ABSTRACT

This present disclosure discloses a light-emitting device, preparation method therefor, and electronic apparatus including same. The light-emitting device including: a first substrate provided with a plurality of bottom electrode regions thereon, the plurality of bottom electrode regions include first bottom electrode regions, second bottom electrode regions, and third bottom electrode regions corresponding to first sub-pixels, second sub-pixels, and third sub-pixels; a pixel-defining layer on the first substrate, the pixel-defining layer having a plurality of openings formed therein, the plurality of openings each expose a corresponding bottom electrode region of a corresponding sub-pixel; a bank layer on the first substrate, the bank layer having a plurality of openings separated from each other formed therein; and a functional stack including first stack part, second stack part, and third stack part, the first stack part, the second stack part and each stack part at least includes a light-emitting layer.

### TECHNICAL FIELD

The present disclosure relates to a light-emitting device, a preparation method therefor, and an electronic apparatus including same.

### BACKGROUND

Light-emitting devices such as light-emitting diodes are widely used in the fields of lighting and display. In related fields, functional layers in light-emitting devices can be prepared using, for example, inkjet printing method.

In the prior art, the RGB sub-pixels in a pixel are usually all arranged as long stripes to form a three-row arrangement. As shown in FIG. 7, the sub-pixels 803, 805, and 807 are arranged side by side and are spaced apart by banks 801. However, as the requirement for pixel density increases, the width of the sub-pixels needs to be relatively narrow in this arrangement, and thus the requirement for printing precision becomes higher. In addition, the volume for containing ink between banks becomes small, so that the ink easily overflows, causing color mixing.

Moreover, as the pixel density increases, the demand for printing accuracy is increasing. This forces some prior art to print not along the length direction of the sub-pixel, but along the width direction of the sub-pixel. However, this is problematic. On the one hand, a printhead with higher physical resolution may be required, with more nozzles corresponding to a single sub-pixel, but even this sometimes requires multiple prints in a manner that achieves higher accuracy, thereby having the problem of multiple alignments and reducing productivity. On the other hand, printing along a narrow side still poses a challenge to printing accuracy and is prone to color mixing.

Accordingly, there exists a need in the prior art for improved light emitting devices, such as lowering the requirements for printing accuracy, increasing the aperture ratio, and improving display performance and light emitting uniformity.

### SUMMARY

According to one aspect of the present disclosure, there is provided a light-emitting device, including: a first substrate provided with a plurality of bottom electrode regions thereon, the plurality of bottom electrode regions include first bottom electrode regions, second bottom electrode regions, and third bottom electrode regions corresponding to first sub-pixels, second sub-pixels, and third sub-pixels, respectively, the first bottom electrode region and the second bottom electrode region are disposed adjacently in a first direction, and the third bottom electrode region is disposed substantially parallel to the first bottom electrode region and the second bottom electrode region; a pixel-defining layer on the first substrate, the pixel-defining layer having a plurality of openings formed therein, wherein the plurality of openings each expose a corresponding bottom electrode region of a corresponding sub-pixel; a bank layer on the first substrate, the bank layer having a plurality of openings separated from each other formed therein, wherein the plurality of openings of the bank layer include first openings, second openings, and third openings, and in a top view, the plurality of openings formed in the pixel-defining layer are each in a corresponding opening formed in the bank layer, and a thickness of the bank layer is greater than a thickness of the pixel-defining layer; and a functional stack including first stack part, second stack part, and third stack part, wherein the first stack part, the second stack part, and the third stack part are disposed in the first to third openings, respectively, and are each located on a corresponding bottom electrode region, and each stack part at least includes a light-emitting layer.

In some embodiments, a plurality of third bottom electrode regions are disposed in the third opening, the plurality of third bottom electrode regions are each disposed in a corresponding opening formed in the pixel-defining layer such that the plurality of third bottom electrode regions are spaced apart from each other along the first direction, and the plurality of third bottom electrode regions are for a plurality of corresponding third sub-pixels, respectively, wherein, the third sub-pixel is a blue sub-pixel, the first sub-pixel is one of a red sub-pixel and a green sub-pixel, and the second sub-pixel is the other of the red sub-pixel and the green sub-pixel.

In some embodiments, in the same pixel, a length of the third bottom electrode region in the first direction is set to be greater than that of a corresponding first bottom electrode region and greater than that of a corresponding second bottom electrode region; and/or in the same pixel, a length of the third bottom electrode region in the first direction is set to be greater than a sum of lengths of corresponding first bottom electrode region and second bottom electrode region.

In some embodiments, in the same pixel, the first bottom electrode region and the second bottom electrode region are configured to be symmetrically disposed with respect to a center line therebetween, and the third bottom electrode region is also configured to be symmetrically disposed with respect to the center line.

In some embodiments, in the third opening, a plurality of third bottom electrode regions separated from each other are disposed; each third bottom electrode region and the first bottom electrode region and the second bottom electrode region disposed on the same side of the third bottom electrode region and adjacent to the third bottom electrode region are configured to be used for the same pixel.

In some embodiments, each first bottom electrode region is a substantially square shape, each second bottom electrode region is a substantially square shape, and each third bottom electrode region is a substantially rectangular shape; and in the same pixel, a width of the first bottom electrode region, a width of the second bottom electrode region, and a width of the third bottom electrode region are configured to be substantially equal, or in the same pixel, a width of the first bottom electrode region and a width of the second bottom electrode region are configured to be substantially equal, and a width of the third bottom electrode region is configured to be greater than the width of the first bottom electrode region.

In some embodiments, the bank layer further includes fourth openings, the fourth opening is disposed substantially parallel to the third opening, and the first opening and the second opening are disposed therebetween; in the fourth opening, a plurality of third bottom electrode regions separated from each other are disposed, the plurality of third bottom electrode regions are separated by the pixel-defining layer, and the third bottom electrode region and the first bottom electrode region and the second bottom electrode region disposed on the same side of the third bottom electrode region and adjacent to the third bottom electrode region are configured to be used for the same pixel.

In some embodiments, the plurality of bottom electrode regions further include fourth bottom electrode regions corresponding to fourth sub-pixels, the first sub-pixel, the second sub-pixel, the third sub-pixel, and the fourth sub-pixel constitute one pixel, and the fourth bottom electrode region is exposed in the third opening and spaced apart from the third bottom electrode region corresponding to the third sub-pixel; the functional stack further includes fourth stack part, the fourth stack part is disposed in the third opening and located on a corresponding fourth bottom electrode region, and the fourth stack part at least includes the light-emitting layer.

In some embodiments, the light-emitting device includes a plurality of pixels arranged as an array in the first direction and a second direction perpendicular to the first direction, wherein, each pixel includes: corresponding first sub-pixel, second sub-pixel, and third sub-pixel; corresponding first bottom electrode region, second bottom electrode region, and third bottom electrode region corresponding to the corresponding first sub-pixel, second sub-pixel, and third sub-pixel; and the first stack part, the second stack part, and the third stack part on the corresponding first bottom electrode region, second bottom electrode region, and third bottom electrode region.

In some embodiments, at least the light-emitting layer of each stack part is prepared by printing ink droplets in the same printing direction and drying, and the printing direction is along a length direction of the third opening, wherein the ink droplets contain a quantum dot material.

In some embodiments, a pixel density of the light-emitting device is 300 PPI or higher.

According to another aspect of the present disclosure, there is provided a preparation method for a light-emitting device, including: providing a first substrate provided with a plurality of bottom electrode regions thereon, wherein the plurality of bottom electrode regions include first bottom electrode regions, second bottom electrode regions, and third bottom electrode regions corresponding to first sub-pixels, second sub-pixels, and third sub-pixels, respectively, the first bottom electrode regions and the second bottom electrode regions are disposed alternately in a first direction, and the third bottom electrode region is disposed substantially parallel to the first bottom electrode region and the second bottom electrode region; forming a bank layer including a plurality of openings separated from each other, the plurality of openings of the bank layer include first openings, second openings, and third openings, and the first opening, the second opening, and third opening each expose the first bottom electrode region, the second bottom electrode region, and the third bottom electrode region, respectively; forming a pixel-defining layer including a plurality of openings, wherein the plurality of openings each expose a corresponding bottom electrode region of a corresponding sub-pixel, and in a top view, the plurality of openings of the pixel-defining layer are each in a corresponding opening of the bank layer; and forming a functional stack including first stack part, second stack part, and third stack part, wherein the first stack part, the second stack part, and the third stack part are disposed in the first to third openings, respectively, and are each located on a corresponding bottom electrode region, and each stack part at least includes a light-emitting layer.

According to another aspect of the present disclosure, there is provided a preparation method for a light-emitting device, including: providing a first substrate provided with a plurality of bottom electrode regions thereon, wherein the plurality of bottom electrode regions include first bottom electrode regions, second bottom electrode regions, and third bottom electrode regions corresponding to first sub-pixels, second sub-pixels, and third sub-pixels, respectively, the first bottom electrode regions and the second bottom electrode regions are disposed alternately in a first direction, and the third bottom electrode region is disposed substantially parallel to the first bottom electrode region and the second bottom electrode region; forming a pixel-defining layer including a plurality of openings, wherein the plurality of openings each expose a corresponding bottom electrode region of a corresponding sub-pixel; forming a bank layer including a plurality of openings separated from each other, wherein in a top view, the plurality of openings of the pixel-defining layer are each in a corresponding opening of the bank layer, and the plurality of openings of the bank layer include first openings, second openings, and third openings, wherein the first opening, the second opening, and the third opening expose the first bottom electrode region, the second bottom electrode region, and the third bottom electrode region, respectively, and a thickness of the bank layer is greater than a thickness of the pixel-defining layer; and forming a functional stack including first stack part, second stack part, and third stack part, wherein the first stack part, the second stack part, and the third stack part are disposed in the first to third openings, respectively, and are each located on a corresponding bottom electrode region, and each stack part at least includes a light-emitting layer.

In some embodiments, a plurality of third bottom electrode regions are disposed in the third opening, the plurality of third bottom electrode regions are each disposed in a corresponding opening of the pixel-defining layer such that the plurality of third bottom electrode regions are spaced apart from each other along the first direction, and the plurality of third bottom electrode regions are for a plurality of corresponding third sub-pixels, respectively, wherein, the third sub-pixel is a blue sub-pixel, the first sub-pixel is one of a red sub-pixel and a green sub-pixel, and the second sub-pixel is the other of the red sub-pixel and the green sub-pixel.

In some embodiments, in the same pixel, a length of the third bottom electrode region in the first direction is set to be greater than a sum of lengths of corresponding first bottom electrode region and second bottom electrode region; and/or in the same pixel, a length of the third bottom electrode region in the first direction is set to be greater than that of a corresponding first bottom electrode region and greater than that of a corresponding second bottom electrode region.

In some embodiments, in the same pixel, the first bottom electrode region and the second bottom electrode region are configured to be symmetrically disposed with respect to a center line therebetween, and the third bottom electrode region is also configured to be symmetrically disposed with respect to the center line.

In some embodiments, in the third opening, a plurality of third bottom electrode regions separated from each other are disposed; each third bottom electrode region and the first bottom electrode region and the second bottom electrode region disposed on the same side of the third bottom electrode region and adjacent to the third bottom electrode region are configured to be used for the same pixel, and the plurality of third bottom electrode regions in the same third opening are separated by the pixel-defining layer.

In some embodiments, each first bottom electrode region is a substantially square shape, each second bottom electrode region is a substantially square shape, and each third bottom electrode region is a substantially rectangular shape; and in the same pixel, a width of the first bottom electrode region, a width of the second bottom electrode region, and a width of the third bottom electrode region are configured to be substantially equal, or in the same pixel, a width of the first bottom electrode region and a width of the second bottom electrode region are configured to be substantially equal, and a width of the third bottom electrode region is configured to be greater than the width of the first bottom electrode region.

In some embodiments, the bank layer further includes fourth openings, the fourth opening is disposed substantially parallel to the third opening, and the first opening and the second opening are disposed therebetween; in the fourth opening, a plurality of third bottom electrode regions separated from each other are disposed, the plurality of third bottom electrode regions are separated by the pixel-defining layer, and the third bottom electrode region and the first bottom electrode region and the second bottom electrode region disposed on the same side of the third bottom electrode region and adjacent to the third bottom electrode region are configured to be used for the same pixel.

In some embodiments, the plurality of bottom electrode regions further include fourth bottom electrode regions corresponding to fourth sub-pixels, the first sub-pixel, the second sub-pixel, the third sub-pixel, and the fourth sub-pixel constitute one pixel, and the fourth bottom electrode region is exposed in the third opening and spaced apart from the third bottom electrode region corresponding to the third sub-pixel; the functional stack further includes fourth stack part, the fourth stack part is disposed in the third opening and located on a corresponding fourth bottom electrode region, and the fourth stack part at least includes the light-emitting layer.

In some embodiments, the light-emitting device includes a plurality of pixels arranged as an array in the first direction and a second direction perpendicular to the first direction, wherein, each pixel includes: corresponding first sub-pixel, second sub-pixel, and third sub-pixel; corresponding first bottom electrode region, second bottom electrode region, and third bottom electrode region corresponding to the corresponding first sub-pixel, second sub-pixel, and third sub-pixel; and the first stack part, the second stack part, and the third stack part on the corresponding first bottom electrode region, second bottom electrode region, and third bottom electrode region.

In some embodiments, at least the light-emitting layer of each stack part is prepared by printing ink droplets in the same printing direction and drying, and the printing direction is along a length direction of the third opening, wherein the ink droplets contain a quantum dot material.

In some embodiments, a pixel density of the light-emitting device is 300 PPI or higher.

According to one aspect of the present disclosure, there is provided an electronic apparatus, including the light-emitting device according to any embodiment described in the present disclosure.

Other features of the present disclosure and advantages thereof will become clear by the following detailed description of exemplary embodiments of the present disclosure with reference to the accompanying drawings.

### BRIEF DESCRIPTION OF THE DRAWINGS

The accompanying drawings, which form part of the specification, depict embodiments of the present disclosure and are used, together with the specification, to explain the principles of the present disclosure.

With reference to the accompanying drawings, the present disclosure may be more clearly understood in the light of the following detailed description, in which:

FIG. 1 shows a schematic top view of a light-emitting device according to an embodiment of the present disclosure;

FIGS. 2 and 3 show schematic top views of the light-emitting device according to embodiments of the present disclosure with some layers removed;

FIGS. 4A and 4B show schematic top views of light-emitting devices according to different embodiments of the present disclosure;

FIG. 5A and FIG. 5B show schematic cross-sectional views of light-emitting devices according to embodiments of the present disclosure;

FIG. 6 shows a schematic flow chart of a method for manufacturing a light-emitting device according to another embodiment of the present disclosure; and

FIG. 7 shows a pixel configuration of the related art as a comparative example.

Note that in the implementations illustrated below, the same accompanying markings are sometimes used in common between different accompanying drawings to denote the same part or parts having the same function, and the repetition of their description is omitted. In this specification, similar marks and letters are used to denote similar items, so that once an item is defined in one of the accompanying drawings, no further discussion thereof is in the subsequent accompanying drawings.

For ease of understanding, the positions, dimensions and ranges, etc., of the various structures shown in the accompanying drawings, etc., sometimes do not indicate actual positions, dimensions and ranges, etc. Accordingly, the disclosed invention is not limited to the positions, dimensions and ranges, etc. disclosed in the accompanying drawings and the like.

### DETAILED DESCRIPTION

Various exemplary embodiments of the present disclosure will now be described in detail with reference to the drawings. It should be noted that the relative arrangements, numerical expressions, and values of the components and steps set forth in these embodiments do not limit the scope of the present disclosure unless otherwise specifically stated. Further, techniques, methods, and apparatus known to one of ordinary skill in the relevant field may not be discussed in detail, but where appropriate, said techniques, methods, and apparatus should be considered part of the granted specification.

It should be understood that the following description of at least one exemplary embodiment is merely illustrative and is not intended to be any limitation of the present disclosure and its application or use. It should also be understood that any of the exemplary implementations described herein are not necessarily indicative of being preferred or advantageous over other implementations. The present disclosure is not limited by any of the expressed or implied theories given in the above-described technical fields, background art, elements of the invention, or specific implementations.

In addition, certain terminology may be used in the following description solely for reference purposes and is thus not intended to be limiting. For example, the words “first”, “second” and other such numerical words referring to structures or components do not imply order or sequence unless the context clearly indicates otherwise.

It should also be understood that the term “include/contain” as used herein indicates the presence of the indicated features, integrals, steps, operations, units, and/or components, but does not preclude the presence or addition of one or more other features, integrals, steps, operations, units, and/or components, and/or combinations thereof.

“Substantially” as used herein is intended to include, in addition to situations where certain conditions are completely met, situations within an acceptable deviation range as determined by those of ordinary skill in the art in view of the measurement and the error associated with measurement of a particular quantity (i.e., limitations of the measurement system).

Furthermore, the singular includes the plural unless otherwise stated.

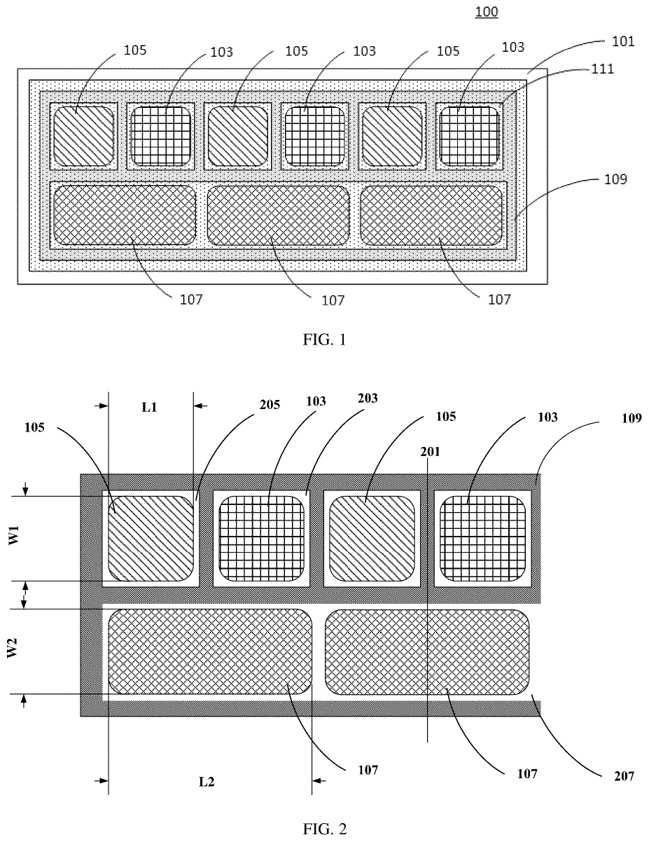

According to one aspect of the present disclosure, a light-emitting device is provided. FIG. 1 shows a schematic top view of a light-emitting device according to an embodiment of the present disclosure. It should be understood that only some of the layers of interest of embodiments of the present application are shown in the drawings and that other layers are omitted so as not to obscure the subject matter.

As shown in FIG. 1, the light-emitting device 100 includes a substrate (first substrate) 101. The substrate 101 is provided with a plurality of bottom electrode regions thereon, including first bottom electrode regions 103, second bottom electrode regions 105, and third bottom electrode regions 107. The first bottom electrode region 103, the second bottom electrode region 105, and the third bottom electrode region 107 may correspond to light-emitting regions of a first sub-pixel, a second sub-pixel, and a third sub-pixel, respectively. Those skilled in the art will appreciate that the light-emitting region of a sub-pixel may include a region of the sub-pixel that is sandwiched between corresponding electrodes and capable of being driven by corresponding electrodes (e.g., an electrode region and a corresponding counter electrode) to emit light, and in some cases may also represent a three-dimensional region bounded by corresponding bank layer and pixel-defining layer.

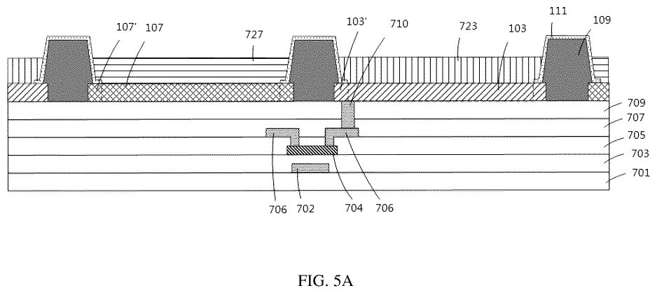

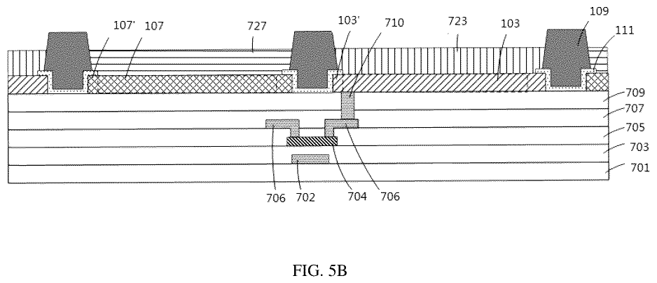

Those skilled in the art will readily appreciate that the bottom electrode region may be at least a part of a corresponding bottom electrode. In practice, the bottom electrodes formed may include parts besides the bottom electrode regions indicated by 103, 105, and 107 in the figure, for example, as better seen from the cross-sectional views in FIGS. 5A and 5B. In the context of the present application, in general, the term “bottom electrode region” is used to refer to the part of a corresponding electrode in the light-emitting region of a pixel or sub-pixel (e.g., the part exposed in the opening of the pixel-defining layer), or may refer to the part of a corresponding electrode that is in contact with the functional stack (which includes a light-emitting layer) of the device. This part is shown in FIGS. 1-5 and is indicated by reference numerals 103, 105, and 107. Here, as an example, each bottom electrode region may be an anode.

As an example, the bottom electrode may include one or more layers of conductive materials, for example, a stack of indium tin oxide (ITO)/silver (Ag)/ITO or a stack of indium zinc oxide (IZO)/Ag/IZO. It should be understood that the present disclosure is not limited thereto. In some embodiments, the bottom electrodes corresponding to different sub-pixels are separated from each other. For example, the first bottom electrode, the second bottom electrode, and the third bottom electrode are disposed independently of each other and are disconnected from each other.

The first bottom electrode regions 103 and the second bottom electrode regions 105 are alternately disposed in a first direction, and the third bottom electrode region 107 is disposed substantially parallel to the first bottom electrode region 103 and the second bottom electrode region 105. As an example, the first direction may be a row direction or a column direction of the pixel array. In some embodiments of the present application, in the same pixel, a length of the third bottom electrode region in the first direction is set to be greater than that of a corresponding first bottom electrode region and greater than that of a corresponding second bottom electrode region; in other embodiments of the present application, in the same pixel, a length of the third bottom electrode region 107 in the first direction may be set to be greater than a sum of lengths of corresponding first bottom electrode region 103 and second bottom electrode region 105, as shown in FIG. 1. Preferably, as shown in the figure, the bottom electrode regions have rounded corners; however, the present disclosure is not limited thereto.

In some embodiments, light emission peak wavelengths of the first sub-pixel, the second sub-pixel, and the third sub-pixel are different from each other. In some embodiments, the third sub-pixel may be a blue sub-pixel, the first sub-pixel may be one of a red sub-pixel and a green sub-pixel, and the second sub-pixel may be the other of the red sub-pixel and the green sub-pixel.

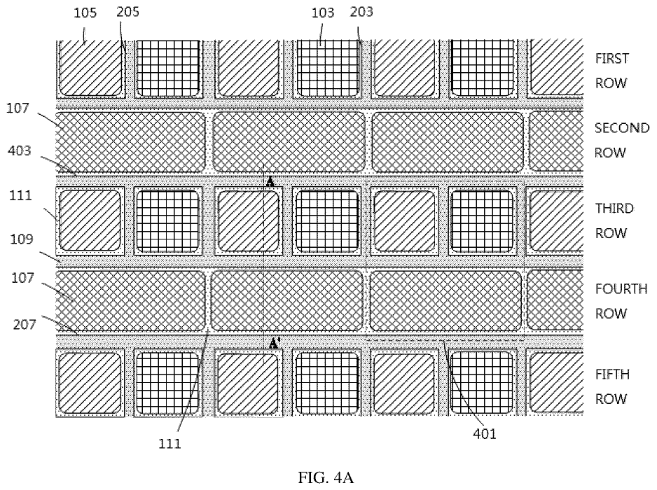

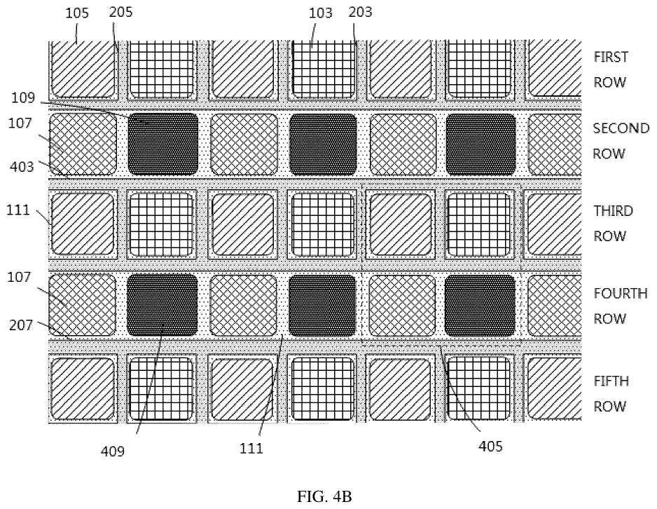

In some embodiments, pixels in the light-emitting device may further include a fourth sub-pixel, and a light emission peak wavelength of the fourth sub-pixel and the light emission peak wavelengths of the first to third sub-pixels may be independently set. A bottom electrode region 409 for the fourth sub-pixel (a fourth bottom electrode region) may also be disposed in a third opening 207. The adjacent first to fourth sub-pixels constitute one pixel. In some embodiments, the light emission peak wavelength of the fourth sub-pixel may be different from the light emission peak wavelengths of the first sub-pixel, the second sub-pixel, and the third sub-pixel. In some other embodiments, the light emission peak wavelength of the fourth sub-pixel may be substantially the same as the emission peak wavelength of one of the first sub-pixel, the second sub-pixel, and the third sub-pixel. For example, the light emission peak wavelength of the fourth sub-pixel may be the same as that of the third sub-pixel. In this case, the bottom electrode region for the third sub-pixel and the bottom electrode region for the fourth sub-pixel in the same pixel may be controlled individually or jointly. In some embodiments, a length of the bottom electrode region 409 for the fourth sub-pixel may be set to be substantially equal to a length of corresponding first bottom electrode region 103 and/or second bottom electrode region 105. In some embodiments, in a top view, the first to fourth sub-pixels constituting one pixel may be arranged in a shape like the Chinese character “H”, as shown in a dashed box indicated by 405 in FIG. 4B. Preferably, light emission peaks of sub-pixels in the third opening are substantially the same, so that the preparation process can be simplified and a light-emitting layer featuring a more uniform film can be formed. In some embodiments, the first bottom electrode region 103 and the second bottom electrode region 105 are configured to be symmetrically disposed with respect to a center line therebetween, and the two bottom electrode regions 107 and 109 corresponding to the third sub-pixel and the fourth sub-pixel, respectively, are also configured to be symmetrically disposed with respect to the center line.

In some embodiments, the light-emitting device 100 further includes a pixel-defining layer (PDL layer) 111 on the first substrate 101. As shown in FIG. 1, the pixel-defining layer 111 may include a plurality of openings, as better shown in FIGS. 5A and 5B. The plurality of openings each expose a corresponding bottom electrode region of a corresponding sub-pixel.

The light-emitting device 100 may further include a bank layer 109 as shown in FIG. 1. As shown in FIG. 1, the bank layer 109 may include a plurality of openings separated from each other. The plurality of openings of the bank layer may include first openings 203, second openings 205, and third openings 207 (see FIG. 2), where the first opening 203, the second opening 205, and the third opening 207 expose corresponding first bottom electrode region 103, second bottom electrode region 105, and third bottom electrode region 107, respectively. Accordingly, the first openings 203 and the second openings 205 may be configured to be alternately disposed in the first direction, and the third opening 207 may be configured to be disposed substantially parallel to the first opening 203 and the second opening 205. As an example, the bank layer may be formed from, for example, a photoresist or silicon oxide.

In some embodiments, the openings formed in the pixel-defining layer are substantially aligned with corresponding openings formed in the bank layer, and the lateral dimension of the opening formed in the pixel-defining layer is smaller than the lateral dimension of the corresponding opening formed in the bank layer. In some embodiments, in a top view, the openings formed in the pixel-defining layer are contained within corresponding openings formed in the bank layer.

Thus, the sub-pixels of different colors (correspondingly, bottom electrode regions) are separated by the bank layer. A thickness of the bank layer (relative to a surface of a side of a bottom electrode away from the substrate) may be 0.5 μm to 2 μm; a too low thickness will result in failure in defining the ink and a too high thickness may affect electrode contact.

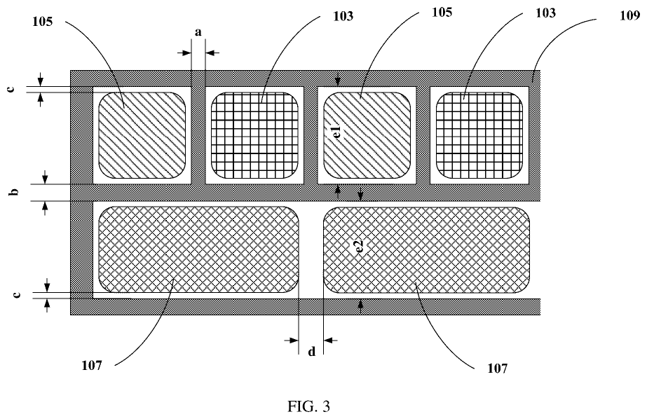

FIGS. 2 and 3 show schematic top views of the light-emitting device 100 according to an embodiment of the present disclosure with the pixel-defining layer 111 and the substrate 101 removed to better illustrate the relationship between the bank layer 107 and the bottom electrode regions 103, 105, and 107. A thickness of the PDL may be set to be between 50 nm and 500 nm, or between 100 nm and 300 nm. The thickness of the PDL may be set in consideration of ensuring uniformity of film formation, compactness and insulating property of the film, and the like.

Materials of the PDL layer may be silicon nitride (SiNₓ), silicon oxide (SiOₓ), silicon oxynitride (SiOₓN_{y}), photoresist (such as polyacrylate resin and/or polyimide resin), or the like. Depending on the material used, the PDL layer may be prepared by, for example, sputtering, or may be prepared by spin coating or coating, and then an unnecessary part may be removed by a patterning process (such as photolithography). In some embodiments, the material and the preparation process of the bank layer may be similar to those of the PDL layer.

The device 100 may further include a functional stack (not indicated, not shown in FIGS. 1-3) at least including a light-emitting layer. As shown in FIGS. 5A and 5B, the functional stack may include a first stack part 723 (corresponding to a first electrode region), a second stack part (not indicated, corresponding to a second electrode region), and a third stack part 727 (corresponding to a third electrode region). The first stack part, the second stack part, and the third stack part are disposed in the first to third openings of the bank layer 109, respectively, and above corresponding bottom electrode regions 103, 105, and 107. Each stack part at least includes a light-emitting layer.

According to some embodiments, at least the light-emitting layer of each stack part may be prepared by printing ink droplets in the same printing direction by a printing device and drying. Preferably, the printing direction may be set to be along a length direction of the third opening (i.e., a length direction of the third bottom electrode region). A quantum dot (QD) material may be contained in the ink droplets, so that a QLED display device may be formed. Although embodiments of the present disclosure are particularly applicable to QLED devices, they may also be applicable to other types of light-emitting/display devices, such as OLEDs prepared by printing and the like.

In the embodiment shown in FIGS. 1-3, only one bottom electrode region 103 and one bottom electrode region 105 are disposed in the openings 203 and 205, respectively; compared with the scheme of providing a plurality of bottom electrode regions in the openings 203 and 205, this scheme is characterized by increased aperture ratio, and the pixels are still regularly arranged in sequence, resulting in a good displaying effect for characters and tables. In the opening 207, a plurality of third bottom electrode regions 107 are disposed. Although two or three third bottom electrode regions 107 are shown in the figure as an example, it should be understood that more third bottom electrode regions 107 may be included. Because the thickness of the pixel-defining layer is relatively low, the ink with the same color on the plurality of bottom electrode regions in the same opening can sufficiently flow and be connected with each other in the preparation process, which is beneficial to improving the uniformity of light emission; in addition, since the plurality of bottom electrode regions are spaced apart from each other, the independent light emission of their corresponding sub-pixels is not affected.

As shown in the figure, the first sub-pixels and the second sub-pixels are disposed alternately in one row, and the third sub-pixels are arranged in another row, so that a wider pixel width can be adopted, thereby reducing the requirement for printing precision and reducing the risk of cross color.

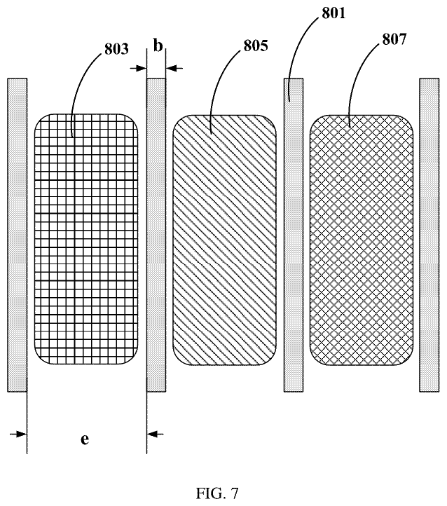

Explanation is made below with reference to the calculation formula. 1 inch=25400 μm, the width of the bank structure in the bank layer is set as b, the interval between adjacent bank structures in the same pixel is set as e, and the printing precision is determined by the width of the short side of the sub-pixel; in FIG. 7, e=(25400/PPI−3b)/3=8467/PPI−b, while in FIG. 3, e1=e2, and so e=(25400/PPI−2b)/2=12700/PPI−b; it can be seen that e can be designed to be wider, so that printing is easier, the precision requirement for the printing device is reduced, and the purchase cost of devices is reduced. Assuming that b is 10 μm and e is 30 μm (existing printing devices can achieve the printing precision at such level), according to the design of FIG. 3, PPI=12700/(e+b), then PPI is 317.5, which can meet the requirements of medium and small-sized display devices, and with the upgrading of printing devices, higher PPI can be achieved.

In addition, as shown in the figure, a bank layer is not disposed between the plurality of third bottom electrode regions 107 of one row, and only isolation by the pixel-defining layer (PDL) is required. Since sub-pixels of the same color are in this row, a pixel isolation structure (e.g., a bank) is not required therebetween, thereby increasing the pixel aperture ratio. In addition, since one or more functional layers (particularly, light-emitting layers) of all the third sub-pixels in one row can communicate with each other, ink for forming the functional layers can freely flow in the long strip-like region of the opening 207, and thus the ink is uniformly distributed, the film is uniform in thickness, and the uniformity of light emission is improved.

In addition, in this embodiment, the third bottom electrode region 107 is disposed adjacent to and parallel to the first bottom electrode region 103 and the second bottom electrode region 105, and a length of the third bottom electrode region 107 may be set to be greater than a sum of lengths of corresponding first bottom electrode region 103 and second bottom electrode region 105. Preferably, the third sub-pixel is a blue sub-pixel. In general, the luminous efficiency of a red sub-pixel is relatively high, the luminous efficiency of a green sub-pixel is also relatively high, and the luminous efficiency of a blue sub-pixel is relatively low. Therefore, the light emission area of the blue sub-pixel may be increased to enable balanced color rendering of the pixel. In some embodiments, in the same pixel, the sizes of the light-emitting regions of the red and green sub-pixels may be substantially equal, while the size of the light-emitting region of the blue sub-pixel may be twice as large or larger than that of the red or green sub-pixel.

In some embodiments, in the same pixel, the first bottom electrode region 103 and the second bottom electrode region 105 are configured to be symmetrically disposed with respect to a center line 201 therebetween (see FIG. 2), and the third bottom electrode region 107 is also configured to be symmetrically disposed with respect to the center line 201.

Preferably, in the same pixel, a width of the first bottom electrode region 103, a width of the second bottom electrode region 105, and a width of the third bottom electrode region 107 are configured to be substantially equal. In other embodiments, in the same pixel, a width of the first bottom electrode region and a width of the second bottom electrode region are configured to be substantially equal, and a width of the third bottom electrode region is configured to be greater than the width of the first bottom electrode region to increase the service life of the blue sub-pixel.

It should also be understood that while only two or three columns of pixels in a row are schematically shown in FIG. 1, in practice, many rows and columns of pixels (and sub-pixels) can be formed on the substrate, as shown in FIG. 4A, in which rows of openings (and corresponding electrode regions) are shown. In addition, as indicated by a dashed box 401 in FIG. 4A, each pixel includes three sub-pixels arranged in a shape like the Chinese character “ [symbol] ”. As indicated by a dashed box 405 in FIG. 4B, each pixel includes four sub-pixels arranged in a shape like the Chinese character “ [symbol] ”.

In some embodiments, the light-emitting device may include a pixel array having a plurality of pixels, where the plurality of pixels may be arranged as an array in a first direction (e.g., a row direction) and a second direction (e.g., a column direction) perpendicular to the first direction. The pixel may be a pixel as described in the previous embodiments, which includes: corresponding first sub-pixel, second sub-pixel, and third sub-pixel; corresponding first bottom electrode region, second bottom electrode region, and third bottom electrode region corresponding to the corresponding first sub-pixel, second sub-pixel, and third sub-pixel; and the first stack part, the second stack part, and the third stack part above the corresponding first bottom electrode region, second bottom electrode region, and third bottom electrode region.

In some embodiments, as shown in FIG. 2, dimensions of the first bottom electrode region 103 (correspondingly, the light-emitting region of the first sub-pixel) may be set to be the same as dimension of the second bottom electrode region 105 (correspondingly, the light-emitting region of the second sub-pixel), so that the printing process may be simplified. As shown in FIG. 2, the bottom electrode regions 103/105 may have a width W1 and a length L1. In some embodiments, L1 may be set to be substantially equal to W1, so that the bottom electrode regions may be a substantially square shape, which may improve uniform spreading of ink droplets and uniform light emission of the light-emitting layer. The substantially square or substantially rectangular shape may have rounded corners. The bottom electrode region 107 may have a width W2 and a length L2. In some embodiments, W1 may be equal to W2. L2 may be set to be greater than the sum of the lengths of the bottom electrode regions 103 and 105, for example, greater than 2L1.

As shown in FIG. 3, the bottom electrode region 103 (correspondingly, the first sub-pixel) and the bottom electrode region 105 (correspondingly, the second sub-pixel) are separated by a bank layer therebetween, which has a width a. The bottom electrode regions 103/105 are separated from the bottom electrode region 107 (correspondingly, the third sub-pixel) by a bank layer therebetween, which has a width b. In different embodiments, the widths a and b may be the same or different. The bottom electrode regions 103/105/107 are configured to be spaced apart from the banks around them, and in this embodiment, the spacing distances between the bottom electrode regions 103/105/107 and corresponding banks are configured to be the same, all being c; however, in other embodiments, the spacing distances between the bottom electrode regions 103/105/107 and corresponding banks may be configured to be different from each other. Also shown in FIG. 3 is that the distance between the third bottom electrode regions 107 in the same opening 207 is d.

As an example, the widths a and b of the bank layer between sub-pixels of different colors (corresponding bottom electrode regions or light-emitting regions) are each preferably 5-20 μm, for example, 8 μm, 10 μm, 11 μm, 15 μm, etc., and as far as the process is feasible, it is better for a and b to be as narrow as possible. In addition, the width of the bank between two sub-pixels of the same row, e.g., red and green sub-pixels, may be set to be narrower than the width of the bank between the red and green sub-pixels and the corresponding blue sub-pixel. This is because there is no need to consider filling a hole of a drain between red and green sub-pixels in the same row, while the bank between the red and green sub-pixels and the blue sub-pixel is preferably set to have a slightly wider width because it is necessary to consider filling the hole (not shown) of the drain with the bank material.

As an example, the distance c is preferably greater than 0 and less than or equal to 10 μm. If c is 0, that is, there is no space left, the thickness of the pixel region at the edge may be slightly thick due to the edge effect, resulting in non-uniform light emission. In another aspect, as the value of c increases, the aperture ratio decreases.

As an example, the distance d between the bottom electrode regions in the same opening (e.g., the third bottom electrode regions 107 in the opening 207) is preferably 3-20 μm. When choosing the distance d, what should be considered are, in one aspect, ensuring that the electrode can break off after etching, in another aspect, the aperture ratio; an increase in the value of the distance d would reduce the aperture ratio.

According to an embodiment of the present disclosure, the sub-pixels of different colors (correspondingly, bottom electrode regions) are separated by the bank layer. According to some embodiments of the present disclosure, within an opening for the sub-pixel (e.g., red or green sub-pixel) of the same color, a pixel-defining layer (PDL) covers all the regions except for the light-emitting region. In addition, by providing the PDL layer, the light-emitting region of the sub-pixel is separated from the bank layer, such that the influence of defects (e.g., warpage or capillary effect) and the like at the edge of the printed layer on the performance is reduced or eliminated, resulting in uniform light emission.

As an example, the examples shown in FIGS. 1-3 are applicable to settings of display devices with any pixel density below 300 PPI and even above 300 PPI, e.g., 240 PPI, 200 PPI, or 150 PPI. Compared with pixel configuration of prior art shown in FIG. 8, embodiments according to the present disclosure can achieve the same pixel density (pixel per inch, PPI) with a wider sub-pixel width in the case where the same parameters such as inter-pixel bank width and distance between the bottom electrode and the adjacent bank are employed. Therefore, the requirement for printing precision is reduced, and the ink in the opening is allowed to flow and distribute more uniformly, thus improving the uniformity of display.

Furthermore, compared with the prior art (as shown in FIG. 7), embodiments according to the present disclosure can achieve a higher aperture ratio at the same pixel density. In some specific embodiments, in the case of 150 PPI, the embodiment of the present disclosure results in about 7% increase in aperture ratio over the prior art. In the case of 200 PPI, the embodiment of the present disclosure results in about 13% increase in aperture ratio over the prior art. In some embodiments, the aperture ratio of the light-emitting device may reach 50% or more. The increase of the aperture ratio makes it possible to supply power to the pixels with a lower current density, so that the luminance, the service life, and the other performance of the device can be improved. As the pixel density increases, the present disclosure can result in a higher increase of aperture ratio over the prior art.

FIG. 4A shows a schematic top view of a part of a light-emitting device according to an embodiment of the present disclosure. FIGS. 5A and 5B show schematic cross-sectional views of light-emitting devices according to embodiments of the present disclosure.

As shown in FIG. 4A, the first to fifth rows are shown. In the first, third, and fifth rows, the first openings 203 and the second openings 205 are alternately disposed. In the second and fourth rows, the third opening 207 in which a plurality of third bottom electrode regions 107 are disposed is shown. It should be noted that the “first row” to “fifth row” labeled here are for the openings, not for the pixels.

In this embodiment, preferably, each first bottom electrode region 103 is a substantially square shape, each second bottom electrode region 105 is a substantially square shape, and each third bottom electrode region 107 is a substantially rectangular shape. Preferably, in the same pixel, a width of the first bottom electrode region 103, a width of the second bottom electrode region 105, and a width of the third bottom electrode region 107 are configured to be substantially equal. In other embodiments, in the same pixel, a width of the first bottom electrode region and a width of the second bottom electrode region are configured to be substantially equal, and a width of the third bottom electrode region is configured to be greater than the width of the first bottom electrode region to increase the service life of the blue sub-pixel.

As shown in FIG. 4A, the bank layer further includes fourth openings 403 (e.g., an opening 403 in the second row, which is equivalent to a copy of the third opening 207), and a plurality of third bottom electrode regions 107 are also formed in the fourth opening 403, similar to the third opening 207. The fourth opening is disposed substantially parallel to the third opening (e.g., the opening 207 in the fourth row) with a row of alternately arranged first openings 203 and second openings 205 disposed therebetween.

In the fourth opening, a plurality of third bottom electrode regions 107 are separated by a pixel-defining layer. Also, the third bottom electrode region 107, and the first bottom electrode region 103 and the second bottom electrode region 105 disposed on the same side of the third bottom electrode region 107 and adjacent to the third bottom electrode region 107 are configured to be used for the same pixel.

FIG. 4B shows a schematic top view of a part of a light-emitting device according to an embodiment of the present disclosure. As shown in FIG. 4B, the first to fifth rows are shown. In the first, third, and fifth rows, the first openings 203 and the second openings 205 are alternately disposed. In the second and fourth rows, the third opening 207 in which a plurality of third bottom electrode regions 107 and a plurality of fourth bottom electrode regions 409 are disposed is shown. It should be noted that the “first row” to “fifth row” labeled here are for the openings, not for the pixels (or sub-pixels).

In this embodiment, preferably, each first bottom electrode region 103 is a substantially square shape, each second bottom electrode region 105 is a substantially square shape, and the third bottom electrode region 107 and the fourth bottom electrode region 409 are a substantially rectangular shape. Preferably, in the same pixel, a width of the first bottom electrode region 103, a width of the second bottom electrode region 105, and widths of the third bottom electrode region 107 and the fourth bottom electrode region are configured to be substantially equal. Preferably, the widths of the third bottom electrode region 107 and the fourth bottom electrode region are configured to be substantially equal. In other embodiments, in the same pixel, the width of the first bottom electrode region and the width of the second bottom electrode region are configured to be substantially equal, and the width of the third bottom electrode region and the width of the fourth bottom electrode region are configured to be greater than the width of the first bottom electrode region to increase the service life of corresponding sub-pixels.

As shown in FIG. 4B, the bank layer further includes fourth openings 403 (e.g., an opening 403 in the second row, which is equivalent to a copy of the third opening 207), and a plurality of third bottom electrode regions 107 and a plurality of fourth bottom electrode regions 409 are also formed in the fourth opening 403, similar to the third opening 207. The fourth opening is disposed substantially parallel to the third opening (e.g., the opening 207 in the fourth row) with a row of alternately arranged first openings 203 and second openings 205 disposed therebetween.

In the third and fourth openings, between the plurality of third bottom electrode regions 107, between the plurality of fourth bottom electrode regions 409, and between the third bottom electrode region 107 and the fourth bottom electrode region 409, a pixel-defining layer is disposed for separation. The adjacent first bottom electrode region 103, second bottom electrode region 105, third bottom electrode region 107, and fourth bottom electrode region 409 may be configured to be used for the same pixel, as shown in FIG. 4B.

Although the lengths of the third bottom electrode region 107 and the fourth bottom electrode region 409 are shown as being substantially equivalent in FIG. 4B, the present disclosure is not limited thereto. For example, in certain embodiments, the length of the third bottom electrode region 107 may be set to be longer or shorter than the length of the fourth bottom electrode region 409, as required by the application.

In addition, although the third bottom electrode regions 107 and the fourth bottom electrode regions 409 are shown to be alternately disposed in FIG. 4B, the present disclosure is not limited thereto. For example, the third bottom electrode regions 107 may be symmetrically disposed with respect to a center line of corresponding first bottom electrode region 103 and second bottom electrode region 105, and the fourth bottom electrode region 409 may be disposed at one side or both sides of the third bottom electrode region 107.

As an example, the widths a and b of the bank layer between sub-pixels of different colors (corresponding bottom electrode regions or light-emitting regions) are each preferably 5-20 μm, for example, 8 μm, 10 μm, 11 μm, etc. The width of the bank between two sub-pixels of the same row (e.g., red and green sub-pixels) may be set to be narrower than the width of the bank between the red and green sub-pixels and the corresponding blue sub-pixel. This is because there is no need to consider filling a hole of a drain between red and green sub-pixels in the same row, while the bank between the red and green sub-pixels and the blue sub-pixel is preferably set to have a slightly wider width because it is necessary to consider filling the hole of the drain with the bank material.

As an example, the distance c between the bottom electrode region (light-emitting region) of the sub-pixel and the adjacent bank layer is preferably greater than 0 and less than or equal to 10 μm, for example, 5 μm. If the distance c is 0, that is, there is no space left, the thickness of the pixel region at the edge may be slightly thick due to the edge effect, resulting in non-uniform light emission. In another aspect, as the value of c increases, the aperture ratio decreases.

As an example, the distance d between the bottom electrode regions in the same opening is preferably 3-20 μm, such as 8 μm, 10 μm, 11 μm, etc. When choosing the distance d, what should be considered are, in one aspect, ensuring that electrode can break off after etching, in another aspect, the aperture ratio; an increase in the value of the distance d would reduce the aperture ratio.

In this embodiment, similarly to the aforementioned embodiments, at least the light-emitting layer of each stack part may be prepared by printing ink droplets in the same printing direction and drying. Preferably, the printing direction is along a length direction of the third opening. Preferably, a quantum dot (QD) material may be contained in the ink droplets, so that a QLED display device may be formed. Although embodiments of the present disclosure are particularly applicable to QLED devices, they may also be applicable to other types of light-emitting/display devices.

The light-emitting device according to this embodiment may be applied to display devices with a pixel density of 300 PPI or any higher pixel density, e.g., 360 PPI, 400 PPI, or even higher. Here, there is no limitation in the pixel density of the display device used, and those skilled in the art can easily design according to actual needs based on the principles of the present disclosure.

FIGS. 5A and 5B show schematic cross-sectional views of light-emitting devices according to different embodiments of the present disclosure along the line A-A′ in FIG. 4. As shown in FIG. 5A, the light-emitting device may include a base substrate 701, which may be a glass substrate or a plastic substrate excellent in mechanical strength, thermal stability, transparency, surface smoothness, ease of handling, and water resistance. A gate 702 for a thin film transistor (TFT) is formed on the substrate 701. A gate dielectric layer 703 is formed above the substrate 701 and the gate 702. A semiconductor layer 704 is disposed oppositely to the gate with the dielectric layer 703 interposed therebetween. The semiconductor layer 704 may be formed from, for example, monocrystalline silicon, polycrystalline silicon, low temperature polycrystalline silicon LTPS, low temperature polycrystalline oxide LTPO, an oxide semiconductor, a doped oxide semiconductor, or the like. An interlayer dielectric layer 705 covers the semiconductor layer 704. Source and drain (and contacts, if desired) 706 are formed on the interlayer dielectric layer 705 and penetrate through the interlayer dielectric layer 705 to be in contact with the semiconductor layer 704. Thereafter, an optional passivation layer 707 and a planarization layer 709 are formed thereon to cover the source and drain, and a via hole 710 enabling access to the source and drain is formed. Here, the substrate on which the TFTs and the corresponding layers are formed may also be referred to as a lower substrate, a TFT substrate, or a first substrate.

It should be understood that the configurations described above are merely illustrative, and the present disclosure may be suitable for use with TFT substrates of various configurations.

In FIG. 5A, a plurality of electrodes (bottom electrodes or first electrodes) 103′ and 107′ are shown to be formed on the TFT substrate (on the planarization layer 709), and the bottom electrodes 103′ and 107′ include the first bottom electrode region 103 and the third bottom electrode region 107, respectively. In the embodiment shown in FIG. 5, as an example, one of the first bottom electrode regions 103 is shown to be connected to one of the source and drain 706 to illustrate the control of the bottom electrode (i.e., to the corresponding bottom electrode region) by the corresponding TFT. The present disclosure is not limited thereto. There may be a plurality of TFTs to control each corresponding bottom electrode (and corresponding bottom electrode region).

As shown in FIG. 5A, a patterned bank layer 109 is formed to achieve isolation between sub-pixels of different colors. As described above, the bank layer 109 has the first to third openings. In this embodiment, a patterned pixel-defining layer (PDL) 111 is also formed on the bank layer 109 and the TFT substrate. An opening is formed in the PDL layer 111 at a set light-emitting region of the sub-pixel to define the light-emitting region. The bottom electrodes 103′ and 107′ are partially covered by the PDL layer 111 and regions of the bottom electrodes at the openings of the light-emitting region are exposed, thereby forming, for example, the aforementioned bottom electrode regions 103 and 107. The same applies to the bottom electrode region 105, although the bottom electrode region 105 is not shown in FIG. 5A.

Although the pixel-defining layer 111 is shown as being formed on the bank layer 109 in FIG. 5A, the present disclosure is not limited thereto, as long as the pixel-defining layer 111 can expose the corresponding bottom electrode region and define the light-emitting region of the sub-pixel. In some embodiments, the bank layer 109 may be formed on the pixel-defining layer 111, as shown in FIG. 5B.

Thereafter, a functional stack, i.e., a stack of functional layers, is formed. Multiple parts 721, 723, etc., of the functional stack are shown in FIG. 5A. The functional stack at least includes a light-emitting layer, for example, a QD light-emitting layer. In some embodiments, the functional stack may also include (but is not limited to) at least one of the following: a hole injection layer, a hole transport layer, a hole blocking layer, an electron injection layer, an electron transport layer, an electron blocking layer, and a buffer layer. In the context of the present disclosure, the functional stack may include any layer, except for the electrode layer, the PDL layer, and the bank layer, in the light-emitting device that affects the light emitting or luminous properties of the device. In other words, the functional stack may include any and all layers that may be disposed in the light-emitting region of the light-emitting device and between the bottom electrode region and the top electrode.

FIG. 5B shows an embodiment in which the bank layer 109 is formed on the pixel-defining layer 111, and other components are the same as or identical to those of FIG. 5A and thus a repeated description thereof is omitted.

In the embodiment of the present disclosure, for example, ink droplets containing a material for forming a functional layer are jet-printed by nozzles at regions between the banks 109 on the substrate to form a functional layer, such as a light-emitting layer or the like. In some embodiments, at least the light-emitting layer may be prepared by means of ink-jet printing, and the other functional layers may be prepared by methods such as deposition, sputtering, coating, or the like.

According to the embodiment of the present disclosure, compared with the prior art, under the same pixel density, the width of the sub-pixel is increased, and the width between the banks is increased, so that the requirement for printing precision is reduced. Furthermore, the ink can freely and sufficiently flow in the opening regions, so that the ink is uniformly distributed, the film is uniform in thickness, and the uniformity of light emission is improved. According to the embodiment of the present disclosure, the aperture ratio can be kept high, and thus the luminous performance is improved, and the service life of the device is increased. According to an embodiment of the present disclosure, the sub-pixels of different colors (correspondingly, bottom electrode regions) are separated by the bank layer. According to some embodiments of the present disclosure, within an opening, for the sub-pixel (e.g., red or green sub-pixel) of the same color, a pixel-defining layer (PDL) covers all the regions except for the light-emitting region. In addition, by providing the PDL layer, the light-emitting region of the sub-pixel is separated from the bank layer, such that the influence of defects (e.g., warpage or capillary effect) and the like at the edge of the printed layer on the performance is reduced or eliminated, resulting in uniform light emission.

The light-emitting device may further include an electrode (a second electrode or a top electrode, not shown in the figure), such as a cathode, on the functional stack. As desired, in some implementations, the second electrode may be a full sheet electrode (or a blanket-like electrode) that can cover the functional layers of a plurality of pixels (including sub-pixels). However, the present disclosure is not limited thereto. In some implementations, the second electrode can be configured to allow light emitted by the light-emitting layer to be transmitted therethrough.

The top electrode may be composed of one or more layers of conductive material. As an example, the top electrode may be formed from Ag, magnesium silver (Mg—Ag) alloy, conductive metal oxide, or conductive metal oxide stack structure (such as ITO, IZO, or IZO/Ag/IZO).

The light-emitting device may further include a top electrode encapsulation member, and the encapsulation member may include: an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyvinyl sulfonate, polyoxymethylene, polyarylate, hexamethyldisiloxane, acrylic resin (e.g., polymethyl methacrylate, polyacrylic acid, and/or the like), epoxy-based resin (e.g., aliphatic glycidyl ether (AGE), and/or the like), or any combination thereof; or any combination of inorganic and organic films.

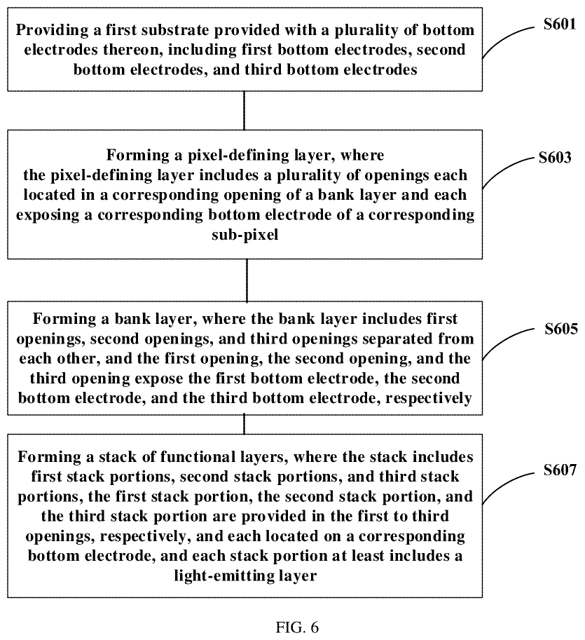

FIG. 6 shows a schematic flow chart of a method for manufacturing a light-emitting device according to another embodiment of the present disclosure.

As shown in FIG. 6, in step S601, a first substrate provided with a plurality of bottom electrode regions thereon is provided. The plurality of bottom electrode regions include first bottom electrode regions, second bottom electrode regions, and third bottom electrode regions corresponding to first sub-pixels, second sub-pixels, and third sub-pixels, respectively, the first bottom electrode regions and the second bottom electrode regions are disposed alternately in a first direction, and the third bottom electrode region is disposed substantially parallel to the first bottom electrode region and the second bottom electrode region.

In step S603, a pixel-defining layer is formed, where the pixel-defining layer includes a plurality of openings that each expose a corresponding bottom electrode region of a corresponding sub-pixel.

In step S605, a bank layer is formed, where the bank layer includes a plurality of openings separated from each other, and the plurality of openings of the bank layer include first openings, second openings, and third openings.

The plurality of openings of the pixel-defining layer each correspond to a corresponding opening of the bank layer and extend inward with respect to the corresponding opening of the bank layer, as shown in FIGS. 5A and 5B. In other words, as shown in the top views of FIGS. 1-4, the plurality of openings of the pixel-defining layer are each in a corresponding opening of the bank layer.

In step S607, a functional stack is formed, where the stack includes first stack part, second stack part, and third stack part, the first stack part, the second stack part, and the third stack part are disposed in the first to third openings, respectively, and are each located on a corresponding bottom electrode region, and each stack part at least includes a light-emitting layer.

It should be noted that the step of forming the pixel-defining layer and the step of forming the bank layer and the order thereof are merely illustrative, and the order of the two may be reversed in other embodiments, as shown in FIGS. 5A and 5B.

The various embodiments or instances described above may be freely combined, and the resulting embodiments are also within the scope of the concepts of the present disclosure. The content described in the embodiments shown in FIGS. 1-5 can be applied in the same way or adaptively to method embodiments, and will not be repeated here.

In some embodiments, the ink forming the light-emitting layer may be spread to a height higher than the PDL or lower than the PDL.

The present disclosure also contemplates an electronic apparatus that includes a light-emitting device described according to any embodiment of the present disclosure and obviously easily obtained based on the present disclosure. In some embodiments, the electronic apparatus may be a large electronic apparatus, such as a television set, a monitor, and/or an outdoor billboard. In other embodiments, the electronic apparatus may be a small or medium-sized electronic apparatus, such as a personal computer, a laptop, a personal digital terminal, a car navigation system, a game console, a smart phone, a tablet computer, and/or a camera.

Those skilled in the art should realize that describing the boundaries between operations (or steps) in the above embodiments is merely illustrative. A plurality of operations may be combined into a single operation, the single operation may be distributed among additional operations, and the operations may be performed at least partially overlapping in time. Moreover, alternative embodiments may include multiple instances of a particular operation, and the order of operations may be altered in various other embodiments. However, other modifications, variations and substitutions are equally possible. Accordingly, this specification and the accompanying drawings should be viewed as illustrative and not limiting.

Although some particular embodiments of the present disclosure have been described in detail by way of examples, it should be understood by those skilled in the art that the above examples are for illustrative purposes only and are not intended to limit the scope of the present disclosure. The embodiments disclosed herein may be combined in any combination without departing from the spirit and scope of the present disclosure. It should also be understood by those skilled in the art that multiple modifications can be made to the embodiments without departing from the scope and spirit of the present disclosure. The scope of the present disclosure is limited by the appended claims.

1. A light-emitting device, comprising:
a first substrate provided with a plurality of bottom electrode regions thereon, wherein the plurality of bottom electrode regions comprise first bottom electrode regions, second bottom electrode regions, and third bottom electrode regions corresponding to first sub-pixels, second sub-pixels, and third sub-pixels, respectively, the first bottom electrode region and the second bottom electrode region are disposed adjacently in a first direction, and the third bottom electrode region is disposed substantially parallel to the first bottom electrode region and the second bottom electrode region;
a pixel-defining layer on the first substrate, the pixel-defining layer having a plurality of openings formed therein, wherein the plurality of openings each expose a corresponding bottom electrode region of a corresponding sub-pixel;
a bank layer on the first substrate, the bank layer having a plurality of openings separated from each other formed therein, wherein the plurality of openings of the bank layer comprise first openings, second openings, and third openings, and in a top view, the plurality of openings formed in the pixel-defining layer are each in a corresponding opening formed in the bank layer, and a thickness of the bank layer is greater than a thickness of the pixel-defining layer; and
a functional stack comprising first stack part, second stack part, and third stack part, wherein the first stack part, the second stack part, and the third stack part are disposed in the first to third openings, respectively, and are each located on a corresponding bottom electrode region, and each stack part at least comprises a light-emitting layer.

2. The light-emitting device according to claim 1, wherein a plurality of third bottom electrode regions are disposed in the third opening,
the plurality of third bottom electrode regions are each disposed in a corresponding opening formed in the pixel-defining layer such that the plurality of third bottom electrode regions are spaced apart from each other along the first direction, and
the plurality of third bottom electrode regions are for a plurality of corresponding third sub-pixels, respectively,
wherein, the third sub-pixel is a blue sub-pixel, the first sub-pixel is one of a red sub-pixel and a green sub-pixel, and the second sub-pixel is the other of the red sub-pixel and the green sub-pixel.

3. The light-emitting device according to claim 1, wherein:
in the same pixel, a length of the third bottom electrode region in the first direction is set to be greater than that of a corresponding first bottom electrode region and greater than that of a corresponding second bottom electrode region; and/or
in the same pixel, a length of the third bottom electrode region in the first direction is set to be greater than a sum of lengths of corresponding first bottom electrode region and second bottom electrode region.

4. The light-emitting device according to claim 1, wherein in the same pixel, the first bottom electrode region and the second bottom electrode region are configured to be symmetrically disposed with respect to a center line therebetween, and the third bottom electrode region is also configured to be symmetrically disposed with respect to the center line.

5. The light-emitting device according to claim 1, wherein:
in the third opening, a plurality of third bottom electrode regions separated from each other are disposed;
each third bottom electrode region and the first bottom electrode region and the second bottom electrode region disposed on the same side of the third bottom electrode region and adjacent to the third bottom electrode region are configured to be used for the same pixel.

6. The light-emitting device according to claim 1, wherein:
each first bottom electrode region is a substantially square shape, each second bottom electrode region is a substantially square shape, and each third bottom electrode region is a substantially rectangular shape; and
in the same pixel, a width of the first bottom electrode region, a width of the second bottom electrode region, and a width of the third bottom electrode region are configured to be substantially equal, or
in the same pixel, a width of the first bottom electrode region and a width of the second bottom electrode region are configured to be substantially equal, and a width of the third bottom electrode region is configured to be greater than the width of the first bottom electrode region.

7. The light-emitting device according to claim 1, wherein the bank layer further comprises fourth openings, the fourth opening is disposed substantially parallel to the third opening, and the first opening and the second opening are disposed therebetween;
in the fourth opening, a plurality of third bottom electrode regions separated from each other are disposed, the plurality of third bottom electrode regions are separated by the pixel-defining layer, and the third bottom electrode region and the first bottom electrode region and the second bottom electrode region disposed on the same side of the third bottom electrode region and adjacent to the third bottom electrode region are configured to be used for the same pixel.

8. The light-emitting device according to claim 1, wherein:
the plurality of bottom electrode regions further comprise fourth bottom electrode regions corresponding to fourth sub-pixels, the first sub-pixel, the second sub-pixel, the third sub-pixel, and the fourth sub-pixel constitute one pixel, and the fourth bottom electrode region is exposed in the third opening and spaced apart from the third bottom electrode region corresponding to the third sub-pixel;
the functional stack further comprises fourth stack part, the fourth stack part is disposed in the third opening and located on a corresponding fourth bottom electrode region, and the fourth stack part at least comprises the light-emitting layer.

9. The light-emitting device according to claim 1, wherein:
the light-emitting device comprises a plurality of pixels arranged as an array in the first direction and a second direction perpendicular to the first direction,
wherein, each pixel comprises: corresponding first sub-pixel, second sub-pixel, and third sub-pixel;
corresponding first bottom electrode region, second bottom electrode region, and third bottom electrode region corresponding to the corresponding first sub-pixel, second sub-pixel, and third sub-pixel; and the first stack part, the second stack part, and the third stack part on the corresponding first bottom electrode region, second bottom electrode region, and third bottom electrode region.

10. (canceled)

11. The light-emitting device according to claim 5, wherein a pixel density of the light-emitting device is 300 PPI or higher.

12. A preparation method for a light-emitting device, comprising:
providing a first substrate provided with a plurality of bottom electrode regions thereon, wherein the plurality of bottom electrode regions comprise first bottom electrode regions, second bottom electrode regions, and third bottom electrode regions corresponding to first sub-pixels, second sub-pixels, and third sub-pixels, respectively, the first bottom electrode regions and the second bottom electrode regions are disposed alternately in a first direction, and the third bottom electrode region is disposed substantially parallel to the first bottom electrode region and the second bottom electrode region;
forming a bank layer comprising a plurality of openings separated from each other, the plurality of openings of the bank layer comprise first openings, second openings, and third openings, and the first opening, the second opening, and third opening each expose the first bottom electrode region, the second bottom electrode region, and the third bottom electrode region, respectively;
forming a pixel-defining layer comprising a plurality of openings, wherein the plurality of openings each expose a corresponding bottom electrode region of a corresponding sub-pixel, and in a top view, the plurality of openings of the pixel-defining layer are each in a corresponding opening of the bank layer; and
forming a functional stack comprising first stack part, second stack part, and third stack part, wherein the first stack part, the second stack part, and the third stack part are disposed in the first to third openings, respectively, and are each located on a corresponding bottom electrode region, and each stack part at least comprises a light-emitting layer.

13. A preparation method for a light-emitting device, comprising:
providing a first substrate provided with a plurality of bottom electrode regions thereon, wherein the plurality of bottom electrode regions comprise first bottom electrode regions, second bottom electrode regions, and third bottom electrode regions corresponding to first sub-pixels, second sub-pixels, and third sub-pixels, respectively, the first bottom electrode regions and the second bottom electrode regions are disposed alternately in a first direction, and the third bottom electrode region is disposed substantially parallel to the first bottom electrode region and the second bottom electrode region;
forming a pixel-defining layer comprising a plurality of openings, wherein the plurality of openings each expose a corresponding bottom electrode region of a corresponding sub-pixel;
forming a bank layer comprising a plurality of openings separated from each other, wherein in a top view, the plurality of openings of the pixel-defining layer are each in a corresponding opening of the bank layer, and the plurality of openings of the bank layer comprise first openings, second openings, and third openings, wherein the first opening, the second opening, and the third opening expose the first bottom electrode region, the second bottom electrode region, and the third bottom electrode region, respectively, and a thickness of the bank layer is greater than a thickness of the pixel-defining layer; and
forming a functional stack comprising first stack part, second stack part, and third stack part, wherein the first stack part, the second stack part, and the third stack part are disposed in the first to third openings, respectively, and are each located on a corresponding bottom electrode region, and each stack part at least comprises a light-emitting layer.

14. The method according to claim 13, wherein a plurality of third bottom electrode regions are disposed in the third opening,
the plurality of third bottom electrode regions are each disposed in a corresponding opening of the pixel-defining layer such that the plurality of third bottom electrode regions are spaced apart from each other along the first direction, and
the plurality of third bottom electrode regions are for a plurality of corresponding third sub-pixels, respectively,
wherein, the third sub-pixel is a blue sub-pixel, the first sub-pixel is one of a red sub-pixel and a green sub-pixel, and the second sub-pixel is the other of the red sub-pixel and the green sub-pixel.

15. The method according to claim 13, wherein:
in the same pixel, a length of the third bottom electrode region in the first direction is set to be greater than a sum of lengths of corresponding first bottom electrode region and second bottom electrode region; and/or
in the same pixel, a length of the third bottom electrode region in the first direction is set to be greater than that of a corresponding first bottom electrode region and greater than that of a corresponding second bottom electrode region.

16. The method according to claim 12, wherein in the same pixel, the first bottom electrode region and the second bottom electrode region are configured to be symmetrically disposed with respect to a center line therebetween, and the third bottom electrode region is also configured to be symmetrically disposed with respect to the center line.

17. The method according to claim 12, wherein:
in the third opening, a plurality of third bottom electrode regions separated from each other are disposed;
each third bottom electrode region and the first bottom electrode region and the second bottom electrode region disposed on the same side of the third bottom electrode region and adjacent to the third bottom electrode region are configured to be used for the same pixel, and
the plurality of third bottom electrode regions in the same third opening are separated by the pixel-defining layer.

18. The method according to claim 13, wherein:
each first bottom electrode region is a substantially square shape, each second bottom electrode region is a substantially square shape, and each third bottom electrode region is a substantially rectangular shape; and
in the same pixel, a width of the first bottom electrode region, a width of the second bottom electrode region, and a width of the third bottom electrode region are configured to be substantially equal, or
in the same pixel, a width of the first bottom electrode region and a width of the second bottom electrode region are configured to be substantially equal, and a width of the third bottom electrode region is configured to be greater than the width of the first bottom electrode region.

19. The method according to claim 13, wherein the bank layer further comprises fourth openings, the fourth opening is disposed substantially parallel to the third opening, and the first opening and the second opening are disposed therebetween;
in the fourth opening, a plurality of third bottom electrode regions separated from each other are disposed, the plurality of third bottom electrode regions are separated by the pixel-defining layer, and the third bottom electrode region and the first bottom electrode region and the second bottom electrode region disposed on the same side of the third bottom electrode region and adjacent to the third bottom electrode region are configured to be used for the same pixel.

20. The method according to claim 13, wherein:
the plurality of bottom electrode regions further comprise fourth bottom electrode regions corresponding to fourth sub-pixels, the first sub-pixel, the second sub-pixel, the third sub-pixel, and the fourth sub-pixel constitute one pixel, and the fourth bottom electrode region is exposed in the third opening and spaced apart from the third bottom electrode region corresponding to the third sub-pixel;
the functional stack further comprises fourth stack part, the fourth stack part is disposed in the third opening and located on a corresponding fourth bottom electrode region, and the fourth stack part at least comprises the light-emitting layer.

21. (canceled)

22. The method according to claim 13, wherein:
at least the light-emitting layer of each stack part is prepared by printing ink droplets in the same printing direction and drying, and the printing direction is along a length direction of the third opening,
wherein the ink droplets contain a quantum dot material.

23. (canceled)

24. An electronic apparatus, comprising the light-emitting device according to claim 1.
